(19) United States
(12) Patent Application Publication
(10) Pub. No.: US 2013/0141878 A1
(43) Pub. Date: Jun. 6, 2013

(54) TRANSFORMER CONDUCTIVE STRUCTURE AND TRANSFORMER

(71) Applicants: Hongyang Wu, Shanghai (CN); Bin Wang, Shanghai (CN); Liping Sun, Shanghai (CN); Jianping Ying, Shanghai (CN)

(72) Inventors: Hongyang Wu, Shanghai (CN); Bin Wang, Shanghai (CN); Liping Sun, Shanghai (CN); Jianping Ying, Shanghai (CN)

(21) Appl. No.: 13/692,556

(22) Filed: Dec. 3, 2012

(30) Foreign Application Priority Data
Dec. 1, 2011 (CN) 201110393371.7
Nov. 2, 2012 (CN) 201210435332.3

(51) Int. Cl. H01F 27/28; H05K 1/18

(52) U.S. Cl. CPC H01F 27/2852; H05K 1/18
USPC 361/748; 336/192

(57) ABSTRACT

The present application discloses a transformer conductive structure, which comprises a primary coiling, a printed circuit board and a secondary coiling unit comprising a plurality of conductive sheets; wherein each conductive sheet comprises an annular body and an output terminal arranged at the edge of the annular body and protruded to the outside; the annular bodies of the conductive sheets and the primary coiling are staggered arrangement together; and the output terminal of the conductive sheet directly clamps on the printed circuit board. The present application further discloses a transformer, which can effectively reduces the output path of the transformer, the AC and DC loss and the volume of the transformer device, so as to increase the power density and efficiency of power supply.

### CROSS REFERENCE TO RELATED APPLICATIONS

The present application claims priority under 35 U.S.C. §119 to Chinese Patent Application No. 201110393371.7, filed on Dec. 1, 2011 and Chinese Patent Application No. 201210435332.3, filed on Nov. 2, 2012, the entire contents of which are incorporated herein by reference.

### FIELD OF THE INVENTION

The present application relates to a transformer conductive structure and a transformer, and particularly to a transformer conductive structure and a transformer for effectively reducing the output path from the transformer to the circuit board and reducing the AC and DC loss.

### BACKGROUND OF THE INVENTION

Today, as power supply has developed towards the direction of high power density, high efficiency and low cost, the design of magnetic devices becomes more and more important, in which the design of power transformer is often the key.

For example, in the integral structure of a conventional DC/DC (Direct Current/Direct Current) converter shown in FIG. 1, the secondary side of a transformer comprises a second winding 101, an output rectifier 102, an output filter 103 and a load terminal 104; and the primary side of the transformer comprises a primary winding 105, a switching element 106 and input terminal 107. In the transformer of prior art, in order to reduce the device structure, technicians have tried to adopt various methods one of which is increasing the switching frequency of the circuit. When the switching frequency of the circuit is increased, the volume of the magnetic core assembly can be reduced effectively. However, high frequency brings many problems to winding design of the transformer: skin effect and proximity effect of the conducting wire in high-frequency working situation will produce additional loss to the transformer windings themselves and between the transformer windings, especially severe in the case of high current output.

As shown in FIG. 2, an input and output side structure of a transformer is further provided in prior art. A primary side of the transformer has a connection between a primary winding 201 and a switching element 202, and the left side of the switching element 202 serves as a input terminal. A secondary side of the transformer has a connection between a second winding 203 and a rectifier and filter element 204, and the right side of the rectifier and filter element 204 is connected to a load. In general, the rectifier and filter element 204, which comprises a rectifier and a filter, is mounted on a PCB (Printed Circuit Board) such that the distance from the lead of the secondary side second winding 203 of the transformer to the rectifier is longer and the AC path therebetween is longer, and the impedance in the secondary side lead ZP (in a circuit having resistance, inductance and capacitance, the effect of resisting AC is called impedance, i.e. parasitic inductance and resistance) will has great loss in high frequency and high current situation, affecting the reliability and efficiency of the circuit. Similarly, the path from the lead of the secondary side second winding 203 to the filter is also longer and the DC loss on it is greater, which occupies much space. That is, the output path of the transformer, the loss and the volume of the transformer device still can not be reduced effectively.

### SUMMARY OF THE INVENTION

The object of the present application is to provide a transformer conductive structure and a transformer, which can effectively reduce the output path of the transformer, the AC and DC loss and the volume of the transformer device, so as to increase the power density and efficiency of power supply.

The above object of the present application is achieved by the following technical solution.

In one aspect, a transformer conductive structure comprises a primary coiling, a printed circuit board, and a secondary coiling unit comprising a plurality of conductive sheets; each conductive sheet comprises an annular body and an output terminal arranged at the edge of the annular body and protruded to the outside; the annular body of the conductive sheet and the primary coiling are coiled together; the output terminals of the conductive sheets directly clamps on the printed circuit board.

The output terminal of the conductive sheet directly clamps on the printed circuit board and is fixed by welding.

Preferably, the output terminal of the conductive sheet comprises a first end and a second end; the first end and the second end are arranged in parallel and opposite to each other up and down.

Both the first end and the second end comprise neck parts and insertion sheet parts.

A plurality of slots which match with the output terminals are arranged on the printed circuit board.

The slots directly clamp the output terminals to fix and conduct the conductive sheets and the printed circuit board directly.

Preferably, the neck part of the first end comprises a transversely folding part the width of which is greater than the width of the slot.

When the output terminal clamps the slot, after the insertion sheet part has passed through the slot, the transversely folding part clamps at the outside of the slot to limit the clamping position of the output terminal.

Preferably, the output terminal and the slot are further fixed by welding after being fixed by clamping.

After the output terminal and the slot being fixed by clamping, the welding is performed at the clamping position where the output terminal and the slot have been clamped such that the conductive sheet is fixed on the printed circuit board.

Preferably, the annular body of the conductive sheet comprises one circle or multi-circle annular metal conductor.

Preferably, two adjacent circles of annular bodies of the conductive sheet therebetween are provided with an insulation layer.

Preferably, the conductive sheet is copper sheet or other metal conductive sheet.

Preferably, the conductive sheets and the primary coiling are coiled together in staggered arrangement.

Preferably, the insertion sheet part is provided with a heat aggregation hole which is near the clamping position where the output terminal and the slot clamp.

Preferably, a rectifying unit and a filtering unit are arranged on the printed circuit board.

The filtering unit comprises a filtering inductance and a filtering capacitance.

The rectifying unit is a patch type rectifying element.

Preferably, copper sheets are attached on the printed circuit board.

Preferably, heat dissipation device is assembled on the rectifying element of the rectifying unit.

Preferably, the printed circuit board is a two-layer or multilayer circuit board.

Preferably, the filtering inductance is configured that a winding of the filtering inductance is a built-in winding of the printed circuit board, the built-in winding being formed by a conductor wiring of the printed circuit board.

The built-in winding of the printed circuit board is formed by patterning one layer or more layers of copper foil of the printed circuit board.

A metal conductor is additionally welded on the conductor wiring of the printed circuit board.

The filtering inductance further comprises a coating magnetic core which is sleeved on the built-in winding of the printed circuit board.

The coating magnetic core is one of a UI type magnetic core, a UU type magnetic core, an EI type magnetic core, an EE type magnetic core, a PQ magnetic core and a single closed magnetic ring.

To achieve the object of the present application, in another aspect a transformer is provided, which is used for connecting with a printed circuit board and comprises a primary coiling and a secondary coiling unit comprising a plurality of conductive sheets; each conductive sheet comprises an annular body and an output terminal arranged at the edge of the annular body and protruded to the outside; the annular body of the conductive sheet and the primary coiling are coiled together; the output terminal of the conductive sheet directly clamps on the printed circuit board.

Preferably, a neck part of the first end comprises a transversely folding part the width of which is greater than the width of a slot.

When the output terminal clamps the slot, after an insertion sheet part has passed through the slot, the transversely folding part clamps at the outside of the slot to limit the clamping position of the output terminal.

Preferably, the output terminal and the slot are further fixed by welding after being fixed by clamping.

After the output terminal and the slot being fixed by clamping, the welding is performed at the clamping position where the output terminal and the slot have been clamped such that the conductive sheet is fixed on the printed circuit board.

Preferably, the annular body of the conductive sheet comprises one circle or multi-circle annular metal conductor.

Preferably, two adjacent circles of annular bodies of the conductive sheet therebetween are provided with an insulation layer.

Preferably, the conductive sheet is copper sheet or other metal conductive sheet.

Preferably, the primary coiling is a single core metal conducting wire or a multi-core metal conducting wire.

The conductive sheets and the primary coiling are in staggered arrangement.

Preferably, the transformer of the present application further comprising a magnetic core set and a plurality of coiling racks; the magnetic core set is provided with a protruding end and the coiling rack is circular; the coiling rack is provided with coiling groove in which the primary coiling winds; and the coiling racks wound with the primary coiling are sleeved on the protruding end of the magnetic core set.

The insulation layer cover the whole annular body of the conductive sheet; the conductive sheet is sleeved on the protruding end of the magnetic core set with the annular body thereof and is sandwiched between every two coiling racks to lead the conductive sheets and the primary coiling in staggered arrangement.

Preferably, the transformer of the present application, further comprising a coiling base, which includes a coiling cylinder the interior of which is a through passage; and the protruding end of the magnetic core set is penetrated into the through passage.

The coiling racks wound with the primary coiling are sleeved on the coiling cylinder; the conductive sheets are sleeved on the coiling cylinder by the annular bodies thereof, and the conductive sheet is sandwiched between every two coiling racks to lead the conductive sheet and the primary coiling in staggered arrangement.

Preferably, a positioning slot is further arranged on the inner circumference of the annular body of the conductive sheet of the transformer, and a positioning strip is arranged on the outer circumference of the coiling cylinder.

When the annular body is sandwiched and sleeved in the coiling groove, the positioning slot is matched with the positioning strip.

Preferably, the outline dimension of the conductive sheet is designed according to the operating frequency, the output power and the specific structure of the magnetic core set of the transformer.

The advantageous effects of the present application are in part that the transformer conductive structure and the transformer of the present application increase the space utilization rate of the printed circuit board and shorten the distance from the lead of the secondary side of the transformer to the output rectifying unit and filtering unit, thereby reduce the AC and DC loss and the volume of the transformer device, increase the power density and efficiency of power supply, and meanwhile increase the heat dissipation function of the transformer.

### BRIEF DESCRIPTION OF THE DRAWING

FIG. 1 is an integral structure diagram examplifying a conventional DC/DC converter;

FIG. 2 is a structure diagram examplifying the primary side and secondary side of a conventional transformer;

FIG. 3 is an assembly schematic diagram examplifying a specific embodiment of a transformer conductive structure and a transformer according to some aspects of the present application;

FIG. 4 is a structure schematic diagram examplifying integrated PCB of a specific embodiment of a transformer conductive structure according to some aspects of the present application;

FIG. 5 is a structure schematic diagram examplifying a conductive sheet of a specific embodiment of a transformer conductive structure according to some aspects of the present application;

FIG. 6 is an enlarged diagram examplifying the output terminal of the conductive sheet of a specific embodiment of a transformer conductive structure according to some aspects of the present application;

FIG. 7 is an assembly schematic diagram examplifying a specific embodiment of a transformer according to some aspects of the present application;

FIG. 8 is an assembly schematic diagram examplifying a coiling base and a coiling rack of a transformer according to some aspects of the present application;

FIG. 9 is a solid structure diagram examplifying a part of a coiling base of a transformer according to some aspects of the present application;

FIG. 10 is a circuit principle diagram examplifying an application example of a transformer conductive structure and a transformer according to some aspects of the present application;

FIG. 11 is a structure schematic diagram examplifying a one circle built-in winding of the printed circuit board according to some aspects of the present application;

FIG. 12 is a structure schematic diagram examplifying a multi-circle built-in winding of the printed circuit board according to some aspects of the present application;

FIG. 13 is a structure schematic diagram examplifying a built-in winding of the printed circuit board welded with a metal conductor additionally according to some aspects of the present application;

FIG. 14 is a sectional structure schematic diagram examplifying a built-in winding of the printed circuit board welded with a metal conductor additionally according to some aspects of the present application;

FIG. 15 is a structure schematic diagram examplifying a filtering inductance 72 formed by a one circle built-in winding of the printed circuit board and a coating magnetic core according to some aspects of the present application;

FIG. 16 is a sectional structure schematic diagram examplifying a filtering inductance 72 formed by a one circle built-in winding of the printed circuit board and a UI type coating magnetic core according to some aspects of the present application;

FIG. 17 is a sectional structure schematic diagram examplifying a filtering inductance 72 formed by a one circle built-in winding 52 of the printed circuit board and a UU type coating magnetic core according to some aspects of the present application;

FIG. 18 is a structure schematic diagram examplifying an embodiment of a filtering inductance 72 formed by a multi-circle built-in winding of the printed circuit board and a coating magnetic core according to some aspects of the present application;

FIG. 19 is a sectional structure schematic diagram examplifying a filtering inductance 72 formed by a multi-circle built-in winding 54 of the printed circuit board and an EI type coating magnetic core according to some aspects of the present application;

FIG. 20A is a sectional structure schematic diagram examplifying an EE type coating magnetic core used for a filtering inductance 72 formed by a built-in winding of the printed circuit board according to some aspects of the present application; and

FIG. 20B is a sectional structure schematic diagram examplifying a PQ type coating magnetic core used for a filtering inductance 72 formed by a built-in winding of the printed circuit board according to some aspects of the present application.

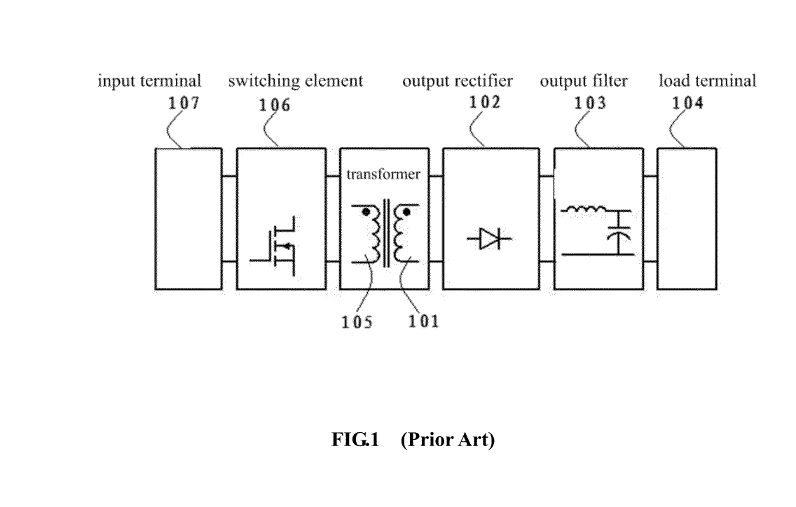

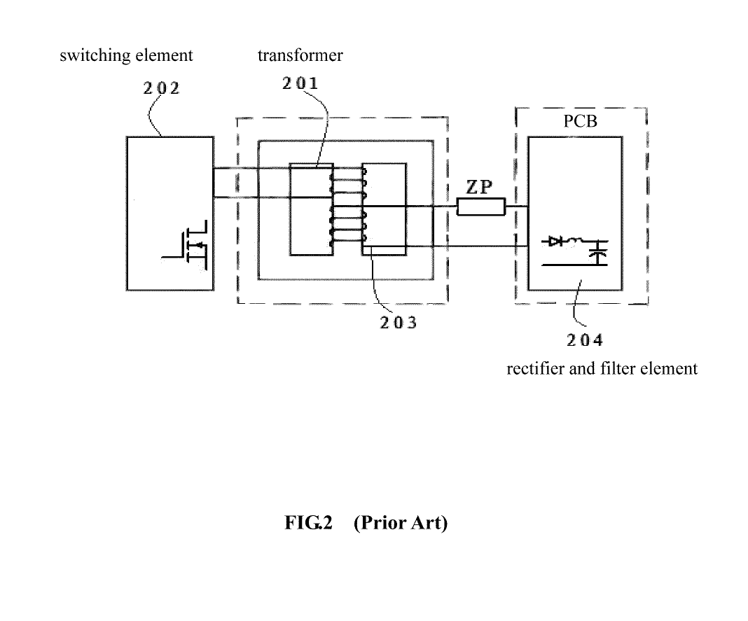

### DESCRIPTION OF THE PREFERRED EMBODIMENTS

To make the objects, technical solutions and advantages of this application more apparent, the present application will be further described in detail hereinafter in conjunction with the accompanying drawings and embodiments. However, it shall be noted that the specific embodiments described below are only used to illustrate the present application but not to limit the scope of the present application.

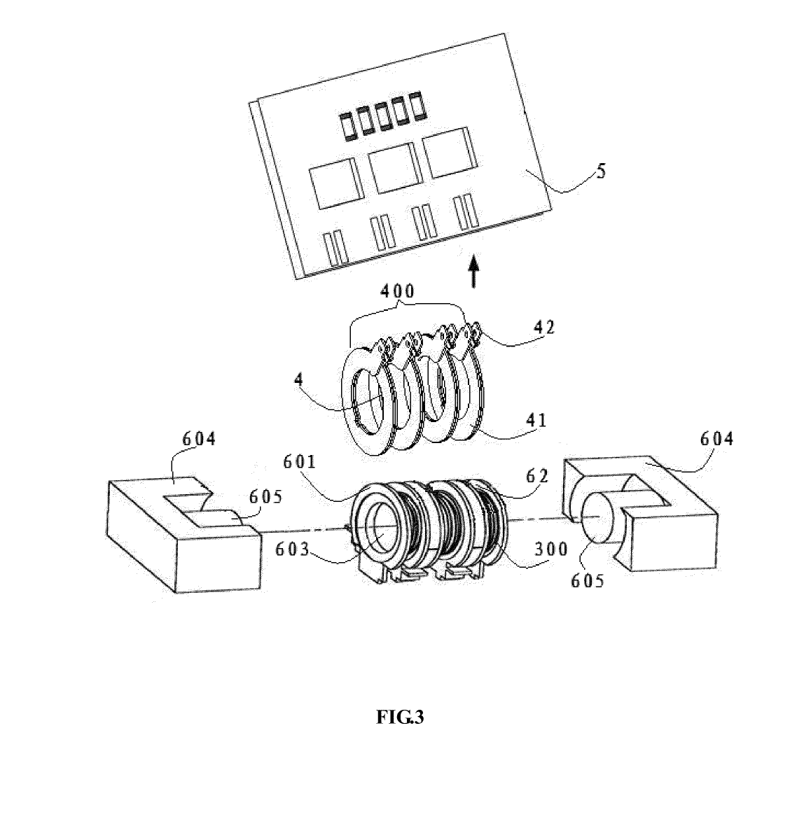

As shown in FIG. 3, a transformer conductive structure in an embodiment of the present application comprises a primary coiling 300 and a secondary coiling unit 400.

The secondary winding unit 400 comprises a plurality of conductive sheets 4 and a printed circuit board 5.

Each conductive sheet 4 comprises an annular body 41 and an output terminal 42 arranged at the edge of the annular body 41 and protruded to the outside.

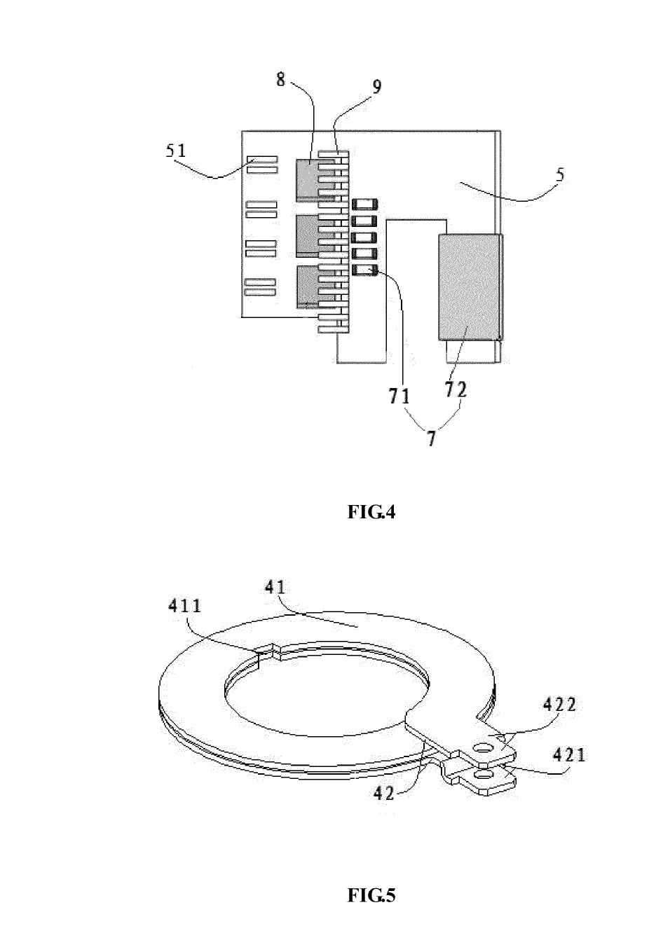

As shown in FIG. 4, a rectifying unit 8 and a filtering unit 7 are arranged on the printed circuit board 5.

In the transformer conductive structure of the embodiment of the present application, the output terminal 42 of the conductive sheet directly clamps on the printed circuit board 5. Thus, the space utilization rate of the printed circuit board 5 is increased and the distance from the lead of the secondary side of the transformer to the output rectifying unit and filtering unit is shortened, thereby the AC and DC loss is reduced, and the power density and efficiency of power supply is increased.

Preferably, as shown in FIG. 5, in the transformer conductive structure in this embodiment, the output terminal 42 of the conductive sheet 4 comprises a first end 421 and a second end 422.

The first end 421 and second end 422 are arranged in parallel and opposite to each other up and down, which is of benefit to effectively reduce the leakage inductance and the AC loss with the transformer in the case of high frequency.

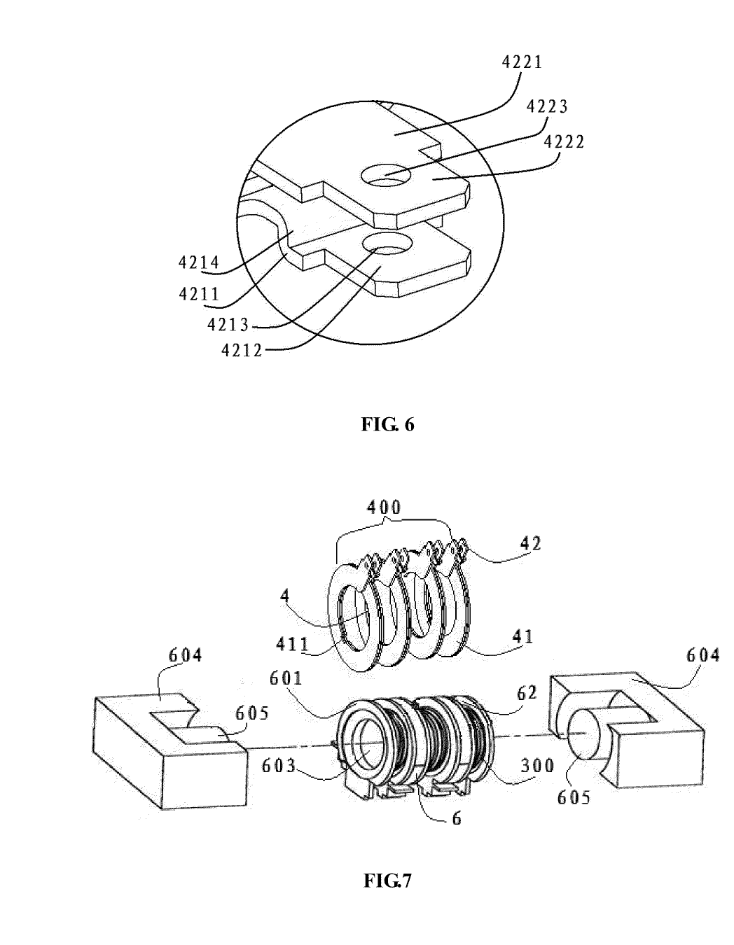

As shown in FIG. 6, the first end 421 comprises a neck part 4211 and an insertion sheet part 4212, and the second end 422 comprises a neck part 4221 and an insertion sheet part 4222.

As shown in FIG. 4, a plurality of slots 51 which can match with the output terminal 42 are arranged on the printed circuit board 5 in this embodiment.

Each slot 51 directly clamps the output terminal 42 of the conductive sheet 4 to fix and conduct the conductive sheet 4 and the printed circuit board 5 directly.

Preferably, as shown in FIG. 6, the neck part 4211 of the first end 421 comprises a transversely folding part 4214 whose width is greater than the width of the slot 51.

When the output terminal 42 clamps the slot 51, after insertion sheet parts 4212, 4222 have passed through the slot 51, the transversely folding part 4214 clamps at the outside of the slot 51 so as to limit the clamping position of the output terminal 42, to make accurate location when the conductive sheet 4 clamps the printed circuit board 5, without the output terminal 42 optionally passing through the slot 51 to cause the clamping easy to loose.

Further, as an embodiment, after being fixed by clamping, the output terminal 42 of the conductive sheet 4 and the slot 51 of the printed circuit board 5 are further fixed by welding.

After the output terminal 42 and the slot 51 being fixed by clamping, the end of the output terminal 42 can expose at the other side of the printed circuit board 5 after passing through the slot 51 or remain in the slot 51. Preferably, a welding is performed at the clamping position where the output terminal 42 and the slot 51 have been clamped such that the conductive sheet 4 is securely fixed on the printed circuit board 5.

Preferably, as an embodiment, the annular body 41 of each conductive sheet 4 can comprise one circle or multi-circle annular metal conductor.

Further, every two adjacent circles of the annular bodies 41 of the conductive sheet 4 therebetween are provided with an insulation layer, which can be insulating tape to wrap each circle of the annular body 41 of the conductive sheet 4 to avoid short circuit between the annular bodies 41, and meanwhile the insulation layer need to be made of high temperature-resistant material.

Further, the conductive sheets 4 are copper sheets or other metal conductive sheets.

Furthermore, as shown in FIG. 3, the conductive sheets 4 and the primary coiling 300 are in staggered arrangement, so as to effectively reduce leakage inductance and AC loss.

Preferably, as shown in FIG. 6, the insertion sheet parts 4212, 4222 are provided with heat aggregation holes 4213, 4223, which are near the clamping position where the output terminal 42 and the slot 51 clamp and can make the solder keep higher temperature for a long time when a welding is performed at the clamping position where the output terminal 42 and the slot 51 have been clamped, which is more beneficial for solder to be coated uniformly, leading the fixation between the conductive sheet 4 and the printed circuit board 5 to be more reliable.

Preferably, as shown in FIG. 4, the filtering unit 7 on the printed circuit board 5 comprises a filtering inductance 72 and a filtering capacitance 71. The rectifying unit 8 on the printed circuit board 5 is a patch type rectifying element, so as to increase the space utilization rate of the printed circuit board 5.

Further, when the current and frequency of each component on the printed circuit board 5 are higher, copper sheets may be attached on the printed circuit board 5 to improve the conduction performance between the electric components, thereby to reduce the loss. The number of copper sheets can be determined according to the layer numbers of the printed circuit board 5 or the amount of current and frequency.

As shown in FIG. 4, on the printed circuit board 5, heat dissipation device 9 is assembled on the rectifying element of the rectifying unit 8 so as to solve the problem of heat dissipation better, especially when the current is higher.

Further, the printed circuit board 5 can be a two-layer or multilayer circuit board according to the requirement of the transformer output power.

The printed circuit board 5 is usually a carrier board, or may be an aluminum substrate with an insulation layer, or may be a metal (such as copper) carrier board with an insulation layer, whose main function is to bear at least a part of the rectifying circuit and the filtering circuit at the secondary side of the transformer. For example, the printed circuit board 5 at least bears the rectifying devices in the rectifying circuit and the filtering inductance 72 in the filtering circuit at the secondary side, and the rectifying devices and the filtering inductance 72 are electrically connected through the printed circuit board 5.

The rectifying circuit at the secondary side of the transformer may be rectifying circuits having various structures such as a full wave rectifying circuit, a current doubled rectifying circuit, a full-bridge rectifying circuit and a half-wave rectifying circuit. The rectifying devices in the rectifying circuit may be the diodes D1 and D2 as shown in FIG. 10, or may be switching elements such as Metal Oxide Semiconductor Field Effect Transistors (MOSFETs) or Bipolar Junction Transistors (BJTs). The rectifying devices may be packaged by surface mounted technologies, or may be packaged by cartridge packages, for example, may be mounted on the circuit board by TO-220 package.

To further shorten the path between the lead of the secondary side of the transformer and the filtering inductance 72 and further reduce the volume of the filtering inductance 72, the filtering inductance 72 in the present application is configured that a winding of the filtering inductance is a one circle or multi-circle PCB conductor wiring (for example, a copper foil wiring) of the printed circuit board on the printed circuit board 50.

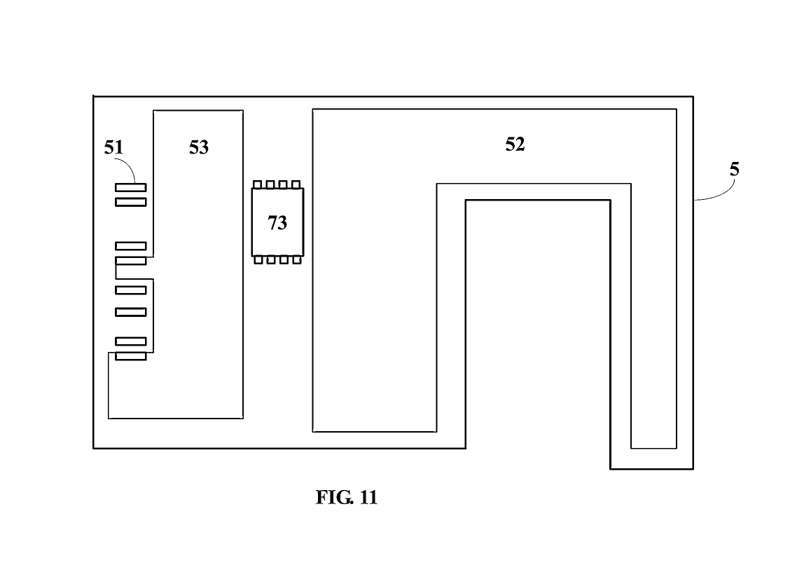

FIG. 11 is a structure schematic diagram examplifying a one circle built-in winding of the printed circuit board according to some aspects of the present application. In addition to the slots 51, conductor wirings 53 of the printed circuit board and electronic elements 73 such as resistors, capacitors, rectifying elements and integrated circuits provided on the printed circuit board 5, a part of conductor wirings of the printed circuit board 5 of the present application is formed as a one circle winding 52, for example, formed by patterning a layer of copper foil of the printed circuit board.

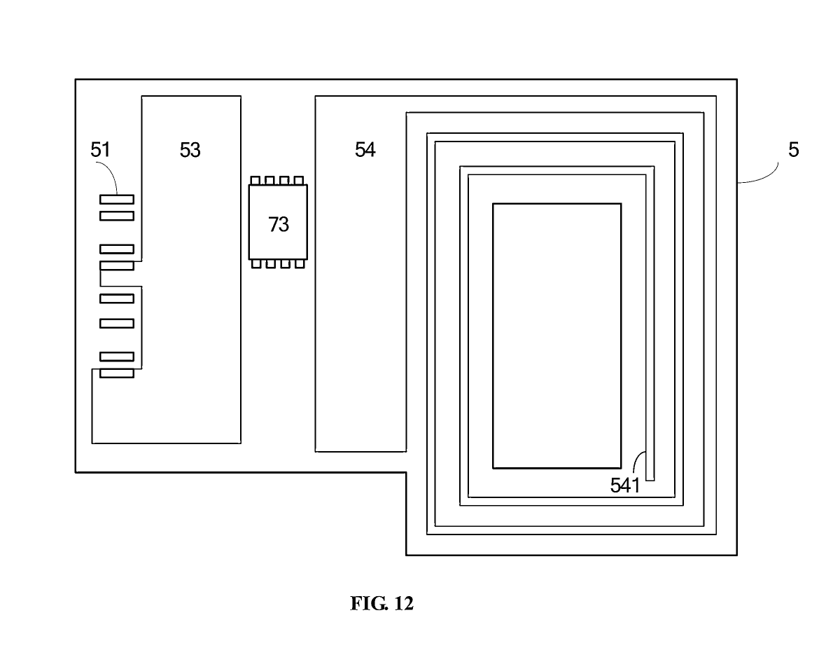

FIG. 12 is a structure schematic diagram examplifying a multi-circle built-in winding of the printed circuit board according to some aspects of the present application. In addition to slots 51, conductor wirings 53 of the printed circuit board and electronic elements 73 such as resistors, capacitors, rectifying elements and integrated circuits provided on the printed circuit board 5, a part of conductor wirings of the printed circuit board 5 of the present application is formed a multi-circle winding 54, for example, formed by patterning one layer or more layers of copper foil of the printed circuit board. For example, a conductor wiring 541 of the multi-circle built-in winding of the printed circuit board may be formed by patterning one layer of copper foil of the printed circuit board.

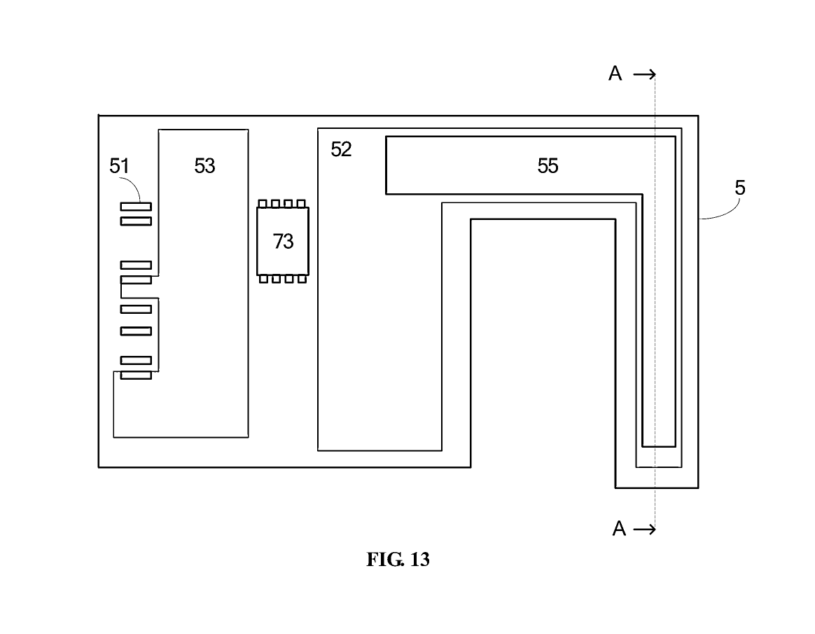

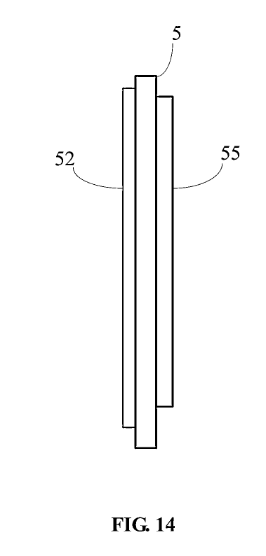

As another embodiment of the present invention, a metal conductor such as copper may be additionally welded on the wirings on the printed circuit board to lower the turn-on impedance of the windings and thereby reduce the conduction loss. FIG. 13 is a structure schematic diagram examplifying a built-in winding of the printed circuit board welded with a metal conductor additionally according to some aspects of the present application. As shown in FIG. 13, a metal conductor 55 is additionally welded on a conductor wiring in parallel with the one circle winding 52 as shown in FIG. 11 to lower the turn-on impedance and thereby reduce the conduction loss. FIG. 14 is a sectional structure schematic diagram examplifying a built-in winding of the printed circuit board welded with a metal conductor additionally according to some aspects of the present application. FIG. 14 is a view taken along the line AA in FIG. 13 when seen toward right. The one circle winding 52 is originally patterned at one side of the printed circuit board 5, and the conductor 55 is additionally welded at the other side of the printed circuit board 5. The conductor 55 may be directly stacked on the one circle winding 52 along the pattern of the one circle winding 52.

As another embodiment, the conductor 55 may be directly stacked on the multi-circle winding 54 along the pattern of the multi-circle winding 54. By additionally welding conductors on the conductor wirings of the windings, the impedance and loss when the winding is turned on is reduced.

If a coating magnetic core is not sleeved on the built-in windings of the printed circuit board as shown in FIGS. 11-14, these built-in windings of the printed circuit board themselves may serve as hollow inductances which may be applied for high frequency filtering of a certain frequency. To increase the amount of inductance, a coating magnetic core may be sleeved on these built-in windings of the printed circuit board.

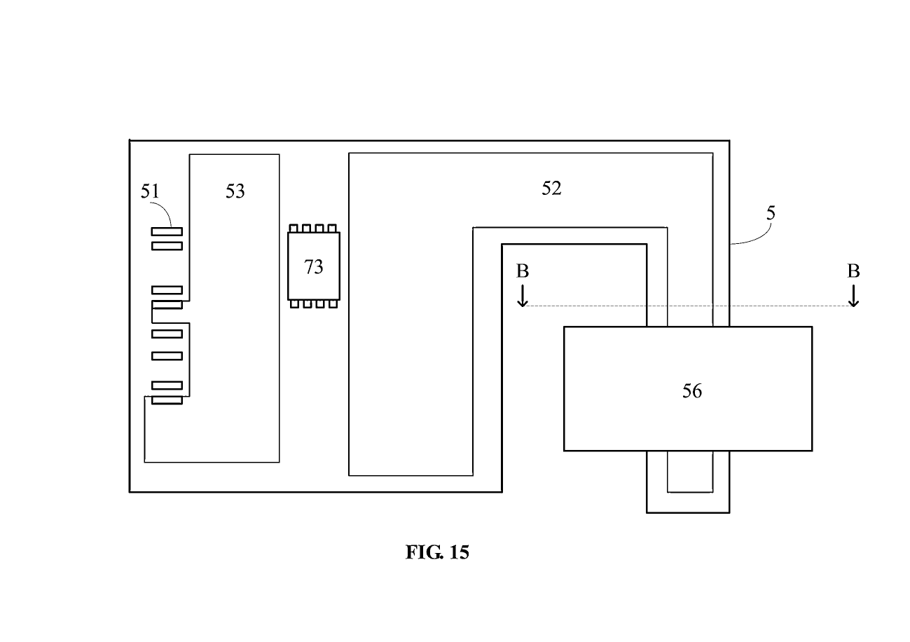

FIG. 15 is a structure schematic diagram examplifying a filtering inductance 72 formed by a one circle built-in winding of the printed circuit board and a coating magnetic core according to some aspects of the present application. Based on FIG. 11, a coating magnetic core 56 is sleeved outside the one circle winding 52 as shown in FIG. 15.

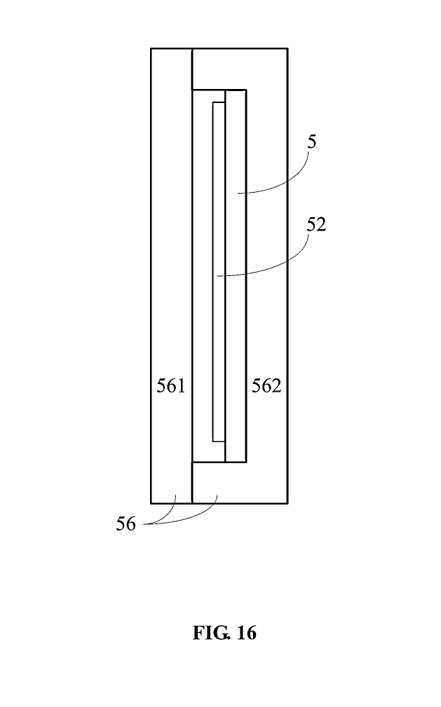

FIG. 16 is a sectional structure schematic diagram examplifying a filtering inductance 72 formed by a one circle built-in winding of the printed circuit board and a UI type coating magnetic core according to some aspects of the present application. FIG. 16 is a view taken along the line BB in FIG. 15 when seen toward right. It can be seen that, the coating magnetic core 56 as shown in FIG. 15 may be a UI type magnetic core, including an I-shaped portion 561 and a U-shaped portion 562 to form a ring-shaped magnetic core surrounding the one circle winding 52. The one circle winding 52 and the UI type coating magnetic core 56 form a filtering inductance 72 with a greater amount of inductance than that of the hollow one circle winding 52.

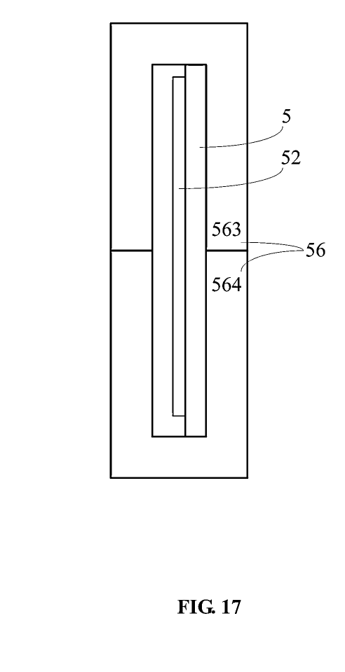

The coating magnetic core as shown in FIG. 15 is not limited to the UI type magnetic core, but also may be other types of magnetic cores. FIG. 17 is a sectional structure schematic diagram examplifying a filtering inductance 72 formed by a one circle built-in winding 52 of the printed circuit board and a UU type coating magnetic core according to some aspects of the present application. FIG. 17 is a view taken along the line BB in FIG. 15 when seen toward right. It can be seen that, the coating magnetic core 56 as shown in FIG. 15 may be a UU type magnetic core, including a U-shaped portion 563 and another U-shaped portion 564 to form a ring-shaped magnetic core surrounding the one circle winding 52. The one circle winding 52 and the UU type coating magnetic core 56 form a filtering inductance 72 with a greater amount of inductance than that of the hollow one circle winding 52.

It should be noted that, both the UI type magnetic core illustrated in FIG. 16 and the UU type magnetic core illustrated in FIG. 17 may be used to configure, in combination with the multi-circle built-in winding of the printed circuit board, a filtering inductance 72 with a greater amount of inductance than that of the hollow one. Furthermore, particularly to the specific shape (i.e., an opening shape) of the printed circuit board as shown in FIG. 11, a single closed magnetic ring may be employed as the coating magnetic core.

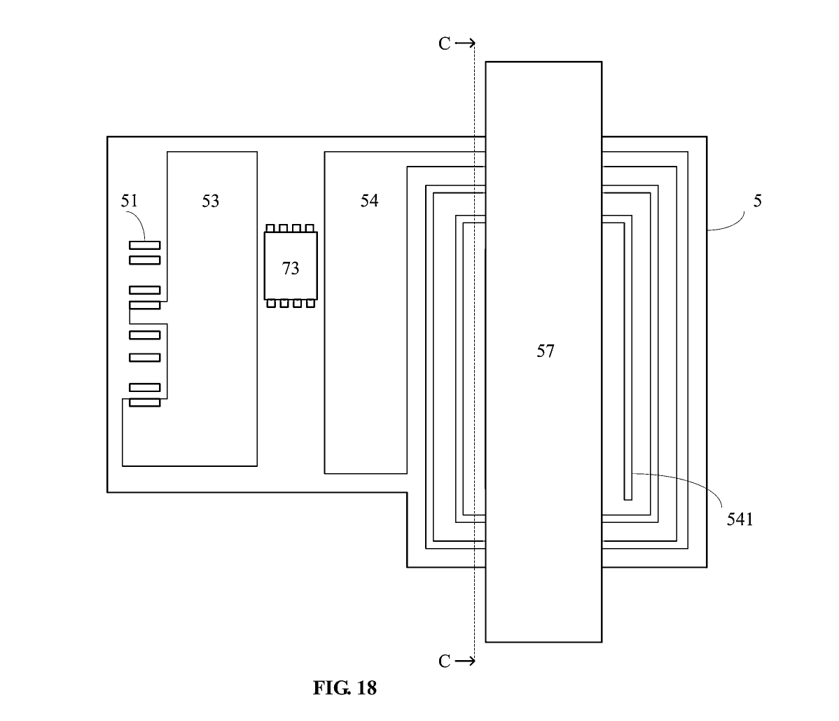

For the one circle or multi-circle built-in winding of the printed circuit board, more types of coating inductances may be sleeved to form a filtering inductance 72 with a greater amount of inductance than that of the hollow one. FIG. 18 is a structure schematic diagram examplifying an embodiment of a filtering inductance 72 formed by a multi-circle built-in winding of the printed circuit board and a coating magnetic core according to some aspects of the present application. Based on FIG. 12, a coating magnetic core 57 is sleeved outside the multi-circle winding 54. It should be understood that, the arrangement of the coating magnetic core 57 is not limited to the in FIG. 18. For example, an arrangement by rotating horizontally 90 degree on the plane of FIG. 18 is also applicable.

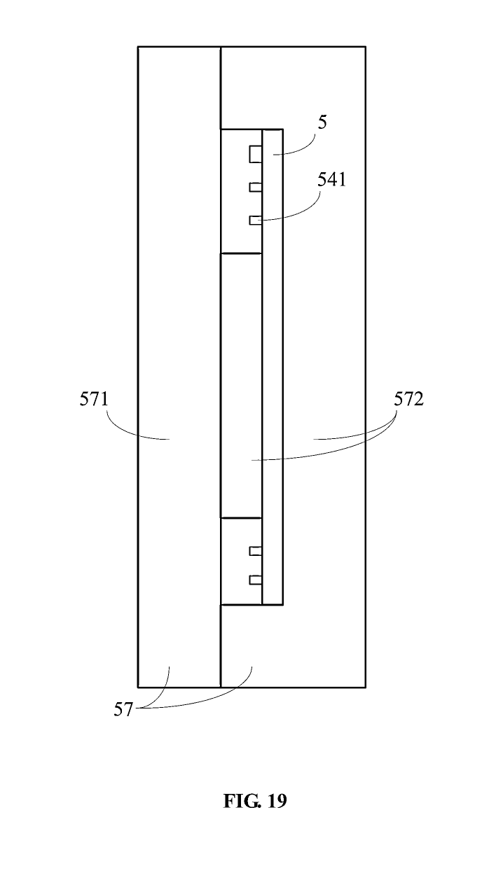

FIG. 19 is a sectional structure schematic diagram examplifying a filtering inductance 72 formed by a multi-circle built-in winding 54 of the printed circuit board and an EI type coating magnetic core according to some aspects of the present application. FIG. 19 is a view taken along the line CC in FIG. 18 when seen toward right. It can be seen that, the coating magnetic core 57 as shown in FIG. 19 is an EI type magnetic core, including an I-shaped portion 571 and an E-shaped portion 572 to form a ring-shaped magnetic core surrounding the multi-circle winding 54. The multi-circle winding 54 and the EI type coating magnetic core 57 form a filtering inductance 72 with a greater amount of inductance than that of the hollow multi-circle built-in winding 54.

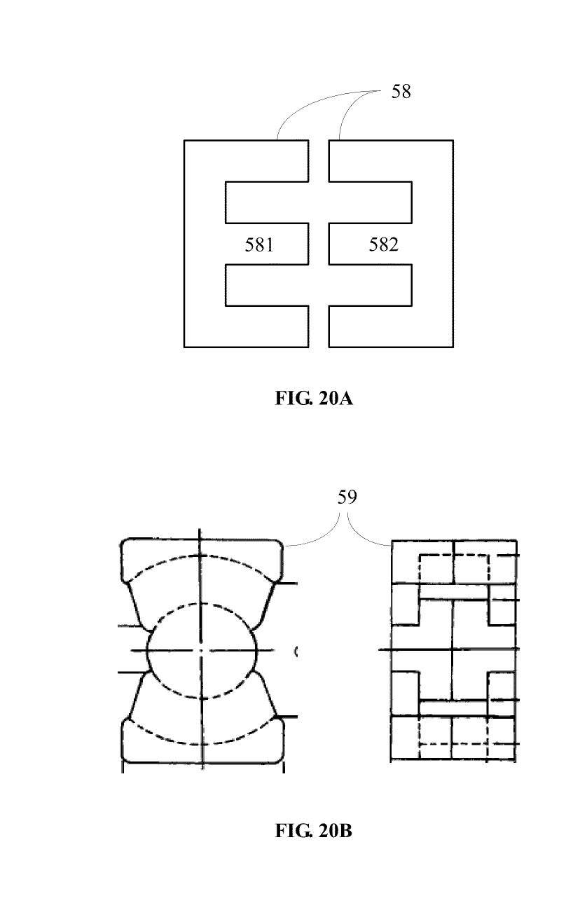

The coating magnetic core as shown in FIG. 18 is not limited to the EI type magnetic core, but may be other types of magnetic cores. FIG. 20A is a sectional structure schematic diagram examplifying an EE type coating magnetic core of a filtering inductance 72 formed by a built-in winding of the printed circuit board according to some aspects of the present application. The EE type coating magnetic core 58 includes an E-shaped portion 581 and an other E-shaped portion 582 to form a ring-shaped magnetic core surrounding the multi-circle winding 54 and thereby form a filtering inductance 72 with a greater amount of inductance as well. FIG. 20B is a sectional structure schematic diagram examplifying a PQ type coating magnetic core used for a filtering inductance 72 formed by a built-in winding of the printed circuit board according to some aspects of the present application. The PQ type coating magnetic core, the three dimensional views of which are similar to that of the magnetic core set 604, may also form a ring-shaped magnetic core surrounding the multi-circle winding 54 and thereby form a filtering inductance 72 with a greater amount of inductance.

It should be noted that, both the EI type magnetic core illustrated in FIG. 19 and the EE type and PQ type magnetic cores illustrated in FIGS. 20A and 20B may be used to configure, in combination with the one circle built-in winding of the printed circuit board, a filtering inductance 72 with a greater amount of inductance than that of the hollow one.

The filtering inductances formed by a built-in winding of the printed circuit board and a coating magnetic core as shown in FIGS. 11-20A may further lower the path between the lead of the secondary side of the transformer and the filtering inductance and further reduce the volume of the filtering inductance.

The transformer conductive structure in the embodiments of the present application increases the space utilization rate of the printed circuit board and shortens the distance from the lead of the secondary side of the transformer to the output rectifying unit and filtering unit, thereby reduces the AC and DC loss, increases the power density and efficiency of power supply, and meanwhile increases the heat dissipation function of the transformer.

### Embodiment 2

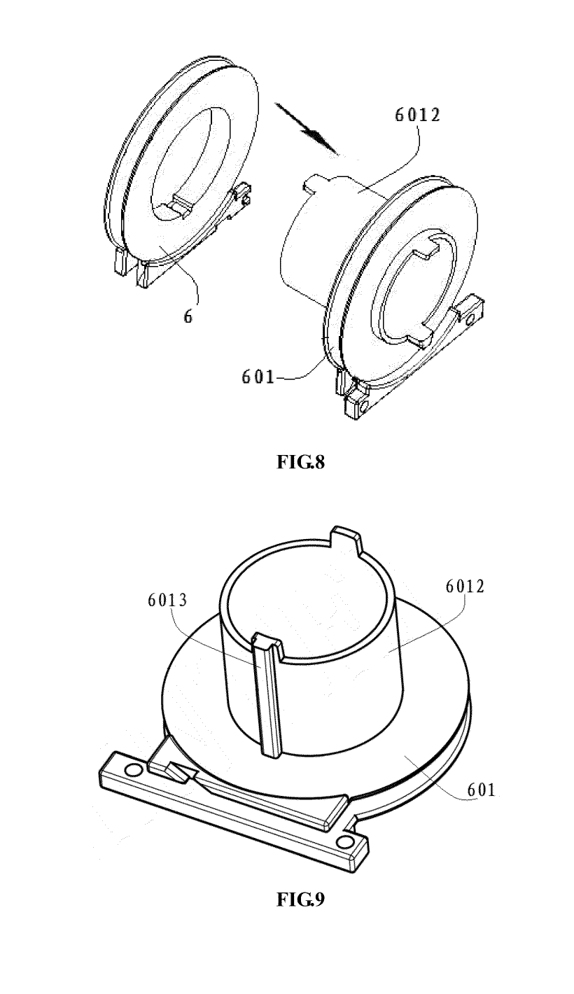

As shown in FIG. 7, a transformer in this embodiment, which is used for connecting with a printed circuit board 5, comprises a primary coiling 300, a plurality of conductive sheets 4 and a pair of magnetic core sets 604.

As an embodiment, the transformer of the present application further comprises a plurality of coiling racks 6 which are circular.

One magnetic core set 604 is provided with a protruding end 605. It shall be noted that the magnetic core set 604 is PQ type in the embodiment or other type as alternatives in other embodiment of the present application.

The coiling racks 6 are sleeved on the protruding end 605 of the magnetic core set 604.

The coiling racks 6 are provided with coiling grooves 62 in which the primary coiling 300 winds. The coiling racks 6 wound with the primary coiling 300 are sleeved on the protruding end 605 of the magnetic core set 604. The conductive sheets 4 are also sleeved on the protruding end 605 of the magnetic core set 604 with the annular bodies 41 thereof, and sandwiched between every two coiling racks 6 to lead the conductive sheets 4 and the primary coiling 300 in staggered arrangement.

Further, when the conductive sheets 4 are sleeved on the protruding end 605 of the magnetic core set 604 with the annular bodies 41 thereof, the insulation layers between the conductive sheets 4 cover the whole annular bodies 41 of the conductive sheets 4 to avoid the direct contact between the annular bodies 41 of the conductive sheets 4 and the protruding end 605 of the magnetic core set. Similarly, in the specific application, after the primary coiling 300 has been wound in the coiling grooves 62, the exposed surface of the primary coiling 300 can also be added with an insulation layer.

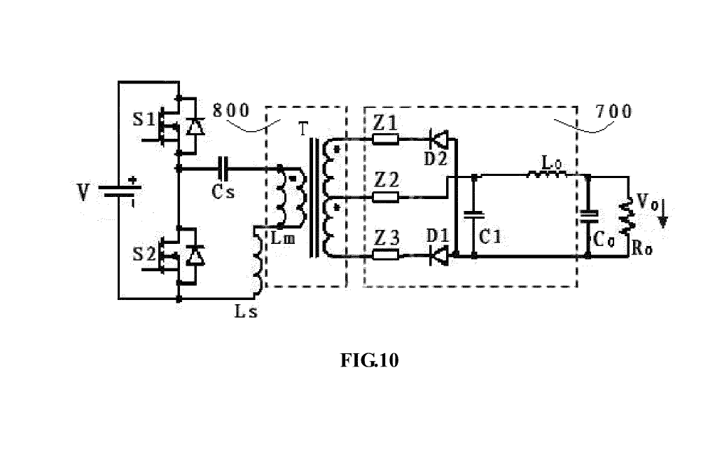

As shown in FIG. 8, as another embodiment, the transformer of the present application can also be provided with a coiling base 601 which includes a coiling cylinder 6012 the interior of which is a through passage 603; and the protruding end 605 of the magnetic core set 604 penetrates into the through passage 603. The coiling racks 6 wound with the primary coiling 300 are sleeved on the coiling cylinder 6012; the conductive sheets 4 are sleeved on the coiling cylinder 6012 by the annular bodies 41 thereof, and the conductive sheets 4 are sandwiched between every two coiling racks 6 to lead the conductive sheets 4 and the primary coiling 300 in staggered arrangement. Thus, the conductive sheets 4 and the coiling racks 6 wound with the primary coiling 300 can be relatively reliably assembled together by using the coiling cylinder 6012, and then be sleeved on the protruding ends 605 of the magnetic core set 604 together with the coiling cylinder 6012.

Preferably, as shown in FIG. 5 and FIGS. 9, when the coiling base 601 is used in the transformer of the present application, a positioning slot 411 is further arranged on the inner circumference of the annular body 41 of the conductive sheet 4, and a positioning strip 6013 is arranged on the outer circumference of the coiling cylinder 6012. When the annular body 41 is sandwiched between the coiling grooves 62, the positioning slot 411 is matched with the positioning strip 6013 to make the conductive sheet 4 accurately positioned and relatively fixed.

Further, the primary coiling 300 is a single core wire or a multi-core wire; the annular body 41 of the conductive sheet is one circle or multi-circle.

Further, in the transformer of the embodiment of the present application, the conductive sheet 4 directly clamps the printed circuit board 5 through its output terminal.

Furthermore, the conductive sheet 4 is copper sheet or other metal conductive sheet, and the specific outline dimension of the conductive sheet 4 needs to be designed according to the operating frequency, the output power and the specific structure of the magnetic core set 604 of the transformer. Other structures of the conductive sheet 4, which are the same as the description in the first embodiment, will not be described repeatedly in the second embodiment.

The specific application of the transformer conductive structure and the transformer of the present application will be further illustrated in conjunction with the first and the second embodiments as follows.

A schematic diagram of a half-bridge LLC series-resonant circuit is shown in FIG. 10. The power of the circuit is 750 W, the output current is 62.5 A and the operating frequency is 70 KHz, wherein Z1, Z2 and Z3 are impedances on the leads; an LLC resonant circuit comprises an inductance Ls, a capacitance Cs and an excitation inductance Lm of the transformer; two main switches form a half-bridge structure, and constant output voltage is achieved by changing the switching frequency. An output filtering unit includes an output high-frequency capacitance C0, an output inductance L0 and a filtering electrolytic capacitor C1. Herein, a printed circuit board equivalent circuit 700 which integrates an output rectifying unit and a filtering unit, corresponds to the printed circuit board 5 in FIG. 4. A transformer equivalent circuit 800 corresponds to the primary coiling 300, the conductive sheets 4, the coiling base 601 and the magnetic core set 604 in FIG. 7, wherein the primary coiling 300 and the conductive sheets 4 are mounted in staggered arrangement. Herein, the output terminal of the transformer equivalent circuit 800 is directly connected to the printed circuit board equivalent circuit 700, which is equivalent to that the output terminals of the conductive sheets 4 are directly connected to the printed circuit board 5 to make the value of Z1, Z2 and Z3 become small, and meanwhile the rectifying unit and the filtering unit are both arranged on the printed circuit board, so the AC and DC loss of the output terminal are both low.

The transformer conductive structure and the transformer of the embodiment integrate the output rectifying unit and the filtering unit on the printed circuit board, and small packaged patch type devices are used as the rectifying devices, so as to increase the space utilization rate of the printed circuit board. Meanwhile the conductive sheets are used for replacing the secondary side wire-wound coil of traditional transformer, so as to increase the heat dissipation function. Extended terminals of the conductive sheets are used for directly connecting with the printed circuit board, so that the distance between the secondary side lead of the transformer and the output rectifier, i.e. AC path, is shortened, so as to reduce the AC and DC loss and the volume of the transformer, and increase the power density and efficiency of power supply.

Finally, it should be noted that, obviously, the people skilled in the art can make various changes and modifications to the present application. Thus, if the changes and modifications of the present application fall into the scope of the claims of the present application and equivalent technology thereof, the present application also intend to includes the changes and modifications.

What is claimed is:

1. A transformer conductive structure, comprising a primary coiling, a printed circuit board, and a secondary coiling unit comprising a plurality of conductive sheets, wherein:
each conductive sheet comprises an annular body and an output terminal arranged at the edge of the annular body and protruded to the outside;
the annular body of the conductive sheet and the primary coiling are coiled together; and
the output terminal of the conductive sheet directly clamps on the printed circuit board.

2. The transformer conductive structure according to claim 1, wherein:
the output terminal of the conductive sheet directly clamps on the printed circuit board and is fixed by welding.

3. The transformer conductive structure according to claim 1, wherein:
the output terminal of the conductive sheet comprises a first end and a second end, and the first end and the second end are arranged in parallel and opposite to each other up and down;
both the first end and the second end comprise neck parts and insertion sheet parts;
a plurality of slots which match with the output terminals are arranged on the printed circuit board; and
the slots directly clamp the output terminals to fix and conduct the conductive sheets and the printed circuit board directly.

4. The transformer conductive structure according to claim 3, wherein the neck part of the first end comprises a transversely folding part the width of which is greater than the width of the slot; and
when the output terminal clamps the slot, after the insertion sheet part has passed through the slot, the transversely folding part clamps at the outside of the slot to limit the clamping position of the output terminal.

5. The transformer conductive structure according to claim 4, wherein the output terminal and the slot are further fixed by welding after being fixed by clamping; and
after the output terminal and the slot being fixed by clamping, the welding is performed at the clamping position where the output terminal and the slot have been clamped such that the conductive sheet is fixed on the printed circuit board.

6. The transformer conductive structure according to claim 1, wherein the annular body of the conductive sheet comprises one circle or multi-circle annular metal conductor.

7. The transformer conductive structure according to claim 3, wherein the annular body of the conductive sheet comprises one circle or multi-circle annular metal conductor.

8. The transformer conductive structure according to claim 4, wherein the annular body of the conductive sheet comprises one circle or multi-circle annular metal conductor.

9. The transformer conductive structure according to claim 5, wherein the annular body of the conductive sheet comprises one circle or multi-circle annular metal conductor.

10. The transformer conductive structure according to claim 6, wherein two adjacent circles of annular bodies of the conductive sheet therebetween are provided with an insulation layer.

11. The transformer conductive structure according to claim 10, wherein the conductive sheet is copper sheet or other metal conductive sheet.

12. The transformer conductive structure according to claim 11, wherein the conductive sheets and the primary coiling are in staggered arrangement together.

13. The transformer conductive structure according to claim 3, wherein the insertion sheet part is provided with a heat aggregation hole, which is near the clamping position where the output terminal and the slot clamp.

14. The transformer conductive structure according to claim 1, wherein a rectifying unit and a filtering unit are arranged on the printed circuit board;
the filtering unit comprises a filtering inductance and a filtering capacitance; and
the rectifying unit is a patch type rectifying element.

15. The transformer conductive structure according to claim 14, wherein copper sheets are attached on the printed circuit board.

16. The transformer conductive structure according to claim 15, wherein a heat dissipation device is assembled on the rectifying element of the rectifying unit.

17. The transformer conductive structure according to claim 14, wherein the printed circuit board is a two-layer or multilayer circuit board.

18. The transformer conductive structure according to claim 14, wherein:
the filtering inductance is configured that a winding of the filtering inductance is a built-in winding of the printed circuit board, the built-in winding being formed by a conductor wiring of the printed circuit board.

19. The transformer conductive structure according to claim 18, wherein:
the built-in winding of the printed circuit board is formed by patterning one layer or more layers of copper foil of the printed circuit board.

20. The transformer conductive structure according to claim 18, wherein:
a metal conductor is additionally welded on the conductor wiring of the printed circuit board.

21. The transformer conductive structure according to claim 18, wherein:
the filtering inductance further comprises a coating magnetic core which is sleeved on the built-in winding of the printed circuit board.

22. The transformer conductive structure according to claim 18, wherein:
the coating magnetic core is one of a UI type magnetic core, a UU type magnetic core, an EI type magnetic core, an EE type magnetic core, a PQ magnetic core and a single closed magnetic ring.

23. The transformer conductive structure according to claim 15, wherein the printed circuit board is a two or multilayer circuit board.

24. The transformer conductive structure according to claim 16, wherein the printed circuit board is a two or multilayer circuit board.

25. A transformer, which is used for connecting with a printed circuit board, comprising a primary coiling and a secondary coiling unit comprising a plurality of conductive sheets; wherein:
each conductive sheet comprises an annular body and an output terminal arranged at the edge of the annular body and protruded to the outside;
the annular body of the conductive sheet and the primary coiling are coiled together; and
the output terminal of the conductive sheet directly clamps on the printed circuit board.

26. The transformer according to claim 25, wherein:
the output terminal of the conductive sheet comprises a first end and a second end;
the first end and the second end are arranged in parallel and opposite to each other up and down;
both the first end and the second end comprise neck parts and insertion sheet parts;
a plurality of slots which match with the output terminals are arranged on the printed circuit board; and
the slots directly clamp the output terminals to fix and conduct the conductive sheets and the printed circuit board directly.

27. The transformer according to claim 26, wherein the neck part of the first end comprises a transversely folding part the width of which is greater than the width of the slot; and
when the output terminal clamps the slot, after the insertion sheet part has passed through the slot, the transversely folding part clamps at the outside of the slot to limit the clamping position of the output terminal.

28. The transformer according to claim 27, wherein the output terminal and the slot are further fixed by welding after being fixed by clamping; and
after the output terminal and the slot being fixed by clamping, the welding is performed at the clamping position where the output terminal and the slot have been clamped such that the conductive sheet is fixed on the printed circuit board.

29. The transformer according to claim 28, wherein the annular body of the conductive sheet comprises one circle or multi-circle annular metal conductor.

30. The transformer according to claim 29, wherein two adjacent circles of annular bodies of the conductive sheet therebetween are provided with an insulation layer.

31. The transformer according to claim 30, wherein the conductive sheet is copper sheet or other metal conductive sheet.

32. The transformer according to claim 31, wherein the primary coiling is a single core metal conducting wire or a multi-core metal conducting wire; and
the conductive sheets and the primary coiling are in staggered arrangement together.

33. The transformer according to claim 25, further comprising a magnetic core set and a plurality of coiling racks, wherein:
the magnetic core set is provided with a protruding end and the coiling rack is circular;
the coiling rack is provided with a coiling groove in which the primary coiling winds, and the coiling racks wound with the primary coiling are sleeved on the protruding end of the magnetic core set; and
the insulation layer cover the whole annular body of the conductive sheet; the conductive sheet is sleeved on the protruding end of the magnetic core set with the annular body thereof and sandwiched between every two coiling racks to lead the conductive sheets and the primary coiling in staggered arrangement.

34. The transformer according to claim 26, further comprising a magnetic core set and a plurality of coiling racks, wherein:
the magnetic core set is provided with a protruding end and the coiling rack is circular;
the coiling rack is provided with a coiling groove in which the primary coiling winds, and the coiling racks wound with the primary coiling are sleeved on the protruding end of the magnetic core set; and
the insulation layer cover the whole annular body of the conductive sheet; the conductive sheet is sleeved on the protruding end of the magnetic core set with the annular body thereof and sandwiched between every two coiling racks to lead the conductive sheets and the primary coiling in staggered arrangement.

35. The transformer according to claim 27, further comprising a magnetic core set and a plurality of coiling racks, wherein:
the magnetic core set is provided with a protruding end and the coiling rack is circular;
the coiling rack is provided with a coiling groove in which the primary coiling winds, and the coiling racks wound with the primary coiling are sleeved on the protruding end of the magnetic core set; and
the insulation layer cover the whole annular body of the conductive sheet; the conductive sheet is sleeved on the protruding end of the magnetic core set with the annular body thereof and sandwiched between every two coiling racks to lead the conductive sheets and the primary coiling in staggered arrangement.

36. The transformer according to claim 28, further comprising a magnetic core set and a plurality of coiling racks, wherein:
the magnetic core set is provided with a protruding end and the coiling rack is circular;
the coiling rack is provided with a coiling groove in which the primary coiling winds, and the coiling racks wound with the primary coiling are sleeved on the protruding end of the magnetic core set; and
the insulation layer cover the whole annular body of the conductive sheet; the conductive sheet is sleeved on the protruding end of the magnetic core set with the annular body thereof and sandwiched between every two coiling racks to lead the conductive sheets and the primary coiling in staggered arrangement.

37. The transformer according to claim 29, further comprising a magnetic core set and a plurality of coiling racks, wherein:
the magnetic core set is provided with a protruding end and the coiling rack is circular;
the coiling rack is provided with a coiling groove in which the primary coiling winds, and the coiling racks wound with the primary coiling are sleeved on the protruding end of the magnetic core set; and
the insulation layer cover the whole annular body of the conductive sheet; the conductive sheet is sleeved on the protruding end of the magnetic core set with the annular body thereof and sandwiched between every two coiling racks to lead the conductive sheets and the primary coiling in staggered arrangement.

38. The transformer according to claim 30, further comprising a magnetic core set and a plurality of coiling racks, wherein:
the magnetic core set is provided with a protruding end and the coiling rack is circular;
the coiling rack is provided with a coiling groove in which the primary coiling winds, and the coiling racks wound with the primary coiling are sleeved on the protruding end of the magnetic core set; and
the insulation layer cover the whole annular body of the conductive sheet; the conductive sheet is sleeved on the protruding end of the magnetic core set with the annular body thereof and sandwiched between every two coiling racks to lead the conductive sheets and the primary coiling in staggered arrangement.

39. The transformer according to claim 31, further comprising a magnetic core set and a plurality of coiling racks, wherein:
the magnetic core set is provided with a protruding end and the coiling rack is circular;
the coiling rack is provided with a coiling groove in which the primary coiling winds, and the coiling racks wound with the primary coiling are sleeved on the protruding end of the magnetic core set; and
the insulation layer cover the whole annular body of the conductive sheet; the conductive sheet is sleeved on the protruding end of the magnetic core set with the annular body thereof and sandwiched between every two coiling racks to lead the conductive sheets and the primary coiling in staggered arrangement.

40. The transformer according to claim 32, further comprising a magnetic core set and a plurality of coiling racks, wherein:
the magnetic core set is provided with a protruding end and the coiling rack is circular;
the coiling rack is provided with a coiling groove in which the primary coiling winds, and the coiling racks wound with the primary coiling are sleeved on the protruding end of the magnetic core set; and
the insulation layer cover the whole annular body of the conductive sheet; the conductive sheet is sleeved on the protruding end of the magnetic core set with the annular body thereof and sandwiched between every two coiling racks to lead the conductive sheets and the primary coiling in staggered arrangement.

41. The transformer according to claim 33, further comprising a coiling base which includes a coiling cylinder the interior of which is a through passage;
wherein the protruding end of the magnetic core set is penetrated into the through passage; and
the coiling racks wound with the primary coiling are sleeved on the coiling cylinder;
the conductive sheets are sleeved on the coiling cylinder by the annular bodies thereof, and the conductive sheet is sandwiched between every two coiling racks to lead the conductive sheets and the primary coiling in staggered arrangement.

42. The transformer according to claim 41, wherein a positioning slot is further arranged on the inner circumference of the annular body of the conductive sheet, and a positioning strip is arranged on the outer circumference of the coiling cylinder; and
when the annular body is sandwiched and sleeved in the coiling groove, the positioning slot is matched with the positioning strip.

43. The transformer according to claim 42, wherein the outline dimension of the conductive sheet is designed according to the operating frequency, the output power and the specific structure of the magnetic core set of the transformer.
